(19) United States
(12) Patent Application Publication
(10) Pub. No.: US 2008/0258255 A1
(43) Pub. Date: Oct. 23, 2008

(54) Electromigration Aggravated Electrical Fuse Structure

(75) Inventors: Po-Yao Ker, Dashe Township (TW); Shine Chung, Taipei Hsien (TW)

Correspondence Address: K & L GATES LLP, 55 SECOND STREET #1700, SAN FRANCISCO, CA, 94105, US

(73) Assignee: Taiwan Semiconductor Manufacturing Co., Ltd.

(21) Appl. No.: 11/738,868

(22) Filed: Apr. 23, 2007

(51) Int. Cl. H01L 23/52; H01L 29/00

(52) U.S. Cl. 257/529; 257/E29.001; 257/E23.141

(57) ABSTRACT

A fuse structure with aggravated electromigration effect is disclosed, which comprises an anode area overlaying a first plurality of contacts that are coupled to a positively high voltage during a programming of the fuse structure, a cathode area overlaying a second plurality of contacts that are coupled to a complementary low voltage during a programming of the fuse structure, and a fuse link area having a first and second end, wherein the first end contacts the anode area at a predetermined distance to the nearest of the first plurality of contacts, and the second end contacts the cathode area at the predetermined distance to the nearest of the second plurality of contacts, wherein the cathode area is smaller than the anode area for the aggravating electromigration effect.

### BACKGROUND

The present invention relates generally to fuse structure in integrated circuits (ICs), and more particularly to electrical fuse structures.

Fuses in an IC are convenient nonvolatile memories for permanently storing information such as “chip-ID”, etc. An electrical fuse is a fuse that can be programmed by applying excessive current or long stress time. One semiconductor material for making such electrical fuse is silicided polysilicon. After stressing the silicided polysilicon material by applying a moderately high current density, typically about 600 mA/um², for a certain period of time, its resistance may rise due to electromigration (EM). The EM is a phenomenon that electrons in an electrical field impacting fixed ions in the fuse, which creates voids and eventually opens a circuit after a prolonged stress. The initial low resistance and the after-stress high resistance may be used to represent two different logic states, commonly known as HIGH and LOW.

In addition to EM, there are two other fuse programming mechanisms, i.e., silicide agglomeration and rupture. The silicide agglomeration happens when the fuse temperature is higher than 850° C., which is beyond the silicide formation temperature. The rupture is physically breaking a fuse when the temperature gradient causing different thermal expansion in different parts of the fuse that causes the break.

For an electrical fuse that has initial resistance of 100 ohm, after an EM programming, its after-stress resistance may range from 500 to 10K ohm. If the same fuse is programmed by silicide agglomeration, its final resistance may reach 100K to 1M ohm. If the fuse is simply ruptured after programming, its final resistance may be more than 10M ohm.

Structures of electrical fuses also affect their programming effectiveness. FIGS. 1A and 1B shows two conventional electrical fuse structures 100 and 150, respectively. Referring to FIG. 1A, the electrical fuse structure 100 has a rectangular anode 102 and a rectangular cathode 112 which is linked to the anode 102 by a fuse link 122. Both the anode 102 and the cathode 112 substantially overlay their respective contacts 134 to utilize contact current density capacities. The anode 102 and the cathode 112 are symmetrical in size. Referring to FIG. 1B, similarly, the electrical fuse structure 150 also has an anode 152, a cathode 162 connected by a fuse link 172. The top and bottom parts of the electrical fuse structure 150 are also symmetrical. A problem with symmetrical structure or larger cathode structure is that the EM effect does not receive a boost as the cathode would have an ample supply of electrons. Lesser EM effect means lesser resistance differentiation between a before and after programming. Even though the fuse link 172 of the electrical fuse structure 150 is tapered toward the middle, there is no reported boost on the EM effect from the tapering.

Kothandaraman, et al. in “Electrically Programmable Fuse Using Electromigration in Silicides”, IEEE Elec. Dev. Lett. Vol. 23, No. 9, September 2002, pp. 523-525, proposed a structure using small anode and large cathode. This structure actually resists the EM effect. The rationale of this structure is to suppress the EM effect such that the rupture could happen at a higher programming voltage that results in a higher resistance state. Alavi et al. in “A PROM Element Based on Salicide Agglomeration of Poly Fuses in a CMOS Logic Process,” IEDM 1997, pp. 855-858, designed a symmetrical fuse structure for electrical fuses, which provides no aggravation to the EM effect. Kalnitsky, et al. in “CoSi2 integrated fuses on poly silicon for low voltage 0.18 um CMOS applications,” IEEE IEDM 1999, pp. 765-768, reported another electrical fuse using EM effect, but it is still based on symmetrical structure.

As such, what is desired is an electrical fuse structure that can aggravate the EM effect which makes a fuse structure easier to be programmed and has a larger resistance differentiation between a before and after programming.

### SUMMARY

In view of the foregoing, the present invention provides a fuse structure with an aggravated electromigration effect. In one aspect of the invention, the fuse structure comprises an anode area overlaying a first plurality of contacts that are coupled to a positively high voltage during a programming of the fuse structure, a cathode area overlaying a second plurality of contacts that are coupled to a complementary low voltage during a programming of the fuse structure, and a fuse link area having a first and second end, wherein the first end contacts the anode area at a predetermined distance to the nearest of the first plurality of contacts, and the second end contacts the cathode area at the predetermined distance to the nearest of the second plurality of contacts, wherein the cathode area is smaller than the anode area for aggravating electromigration effects.

According to another aspect of the present invention, a reverse biased PN junction is formed in the body of the fuse link area to shun current to the surface of the fuse structure for further aggravating the EM effect.

According to yet another aspect of the present invention, the cathode area overlaying the second plurality contacts by a smaller distance than specified by a predetermined design rule for restricting current density at the second plurality of contacts, and therefore, aggravating the EM effect at the same time.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1A and 1B illustrate conventional electrical fuse structures.

FIG. 2 illustrates an electrical fuse structure according to a first embodiment of the present invention.

FIG. 3 is a sectional view of the electrical fuse structure having a reverse biased PN juncture according to a second embodiment of the present invention.

FIGS. 4A and 4B are top views of electrical fuse structures each having a reverse biased PN junction according to the second embodiment of the present invention.

FIG. 5A illustrates a compact electrical fuse structure according to a third embodiment of the present invention.

FIG. 5B illustrates another compact electrical fuse structure having a reverse biased PN junction according to a combination of the second and third embodiment of the present invention.

FIG. 5C illustrates yet another compact electrical fuse structure having a reverse biased PN junction at a cathode-and-fuse-link interface according to a combination of the second and third embodiment of the present invention.

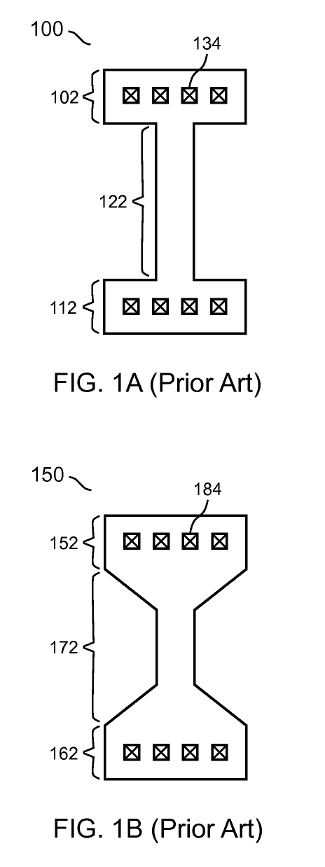

### DESCRIPTION

The following will provide a detailed description of a fuse structure that provides greater resistance differentiation between before and after programming through aggravating electromigration (EM) effects in the fuse structure. The EM effects from which the present invention benefits include a cathode depletion effect and a reservoir effect. The cathode depletion effect refers to a phenomenon that during a programming, the cathode area is more prone to have voids than the anode area. The reservoir effect refers to a phenomenon that the larger the cathode area the more resistant the fuse structure to the EM stress.

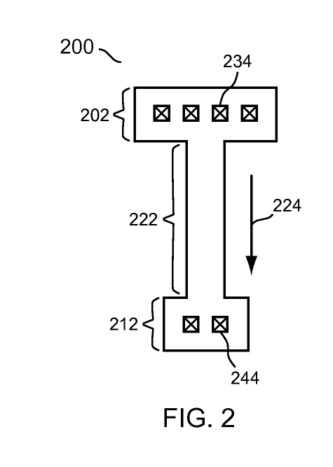

FIG. 2 illustrates an electrical fuse structure 200 according to a first embodiment of the present invention. The electrical fuse structure 200 comprises an anode area 202, a cathode area 212 and a fuse link area 222 connecting the anode area 202 and cathode area 212. Contacts 234 and 244 make connections to the anode area 202 and cathode area 212, respectively. During a programming of the fuse structure 200, a current 224 flows from the anode area 202 to the cathode area 212 causing a resistance of the fuse structure 200 to rise due to the EM effect. Under a given current 224 and a certain stress time, the more severe the EM effect the bigger the resistance differentiation between the before and after programming. Referring to FIG. 2, the cathode area 212 is therefore made smaller than the anode area 202 to aggravate the EM effect according to the first embodiment of the present invention.

Although electrical fuse structure 200 is commonly made of polysilicon material, one having skills in the art would appreciate other materials, such as silicided polysilicon and diffusion or a combination of them, may also be used. Besides, the electrical fuse structure 200 is not limited to be on top of a field oxide. The underneath material may be thin gate oxide, as a programming voltage of such electrical fuse structure 200 is low enough not to cause damage to the gate oxide.

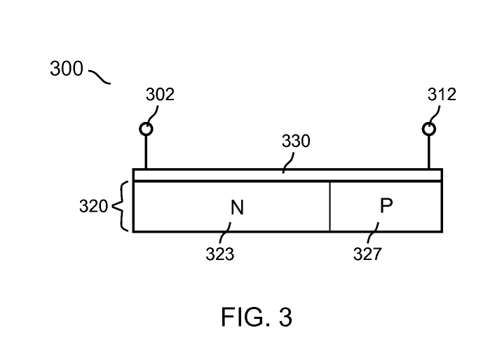

FIG. 3 is a sectional view of the electrical fuse structure 300 having a reverse biased PN juncture in a fuse link area according to a second embodiment of the present invention. Here the electrical fuse structure 300 is made of silicided polysilicon, i.e., a silicide layer 330 is formed on top of a polysilicon layer 320. Prior to the silicide process, the polysilicon 320 is implanted with N-type ions such as arsenic (As) in an area 323 which is coupled to an anode 302. The polysilicon 320 is implanted with P-type ions such as boron (B) in an area 327 which is coupled to a cathode 312. Therefore, the polysilicon 320 has a reverse biased PN junction during programming, which will shun the majority of the programming current to the silicide layer 330. Large currents in turn will more severely stress the fuse structure 300, and cause the resistance of the fuse structure 300 to arise more due to the EM effect.

Although the silicided polysilicon is used to illustrate the second embodiment of the present invention, one having skills in the arts would recognize that the principle of the present invention may be applied to other structures, such as silicide over silicon and anti-fuse structure, as long as a reverse biased PN junction can be formed underneath a layer which is subject to EM effects.

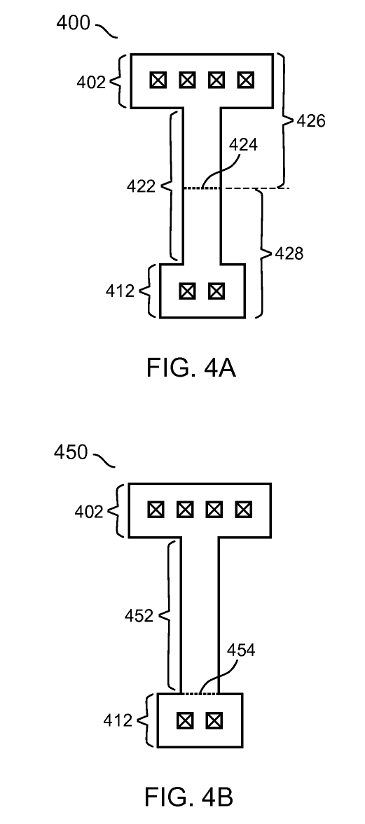

FIGS. 4A and 4B are top views of electrical fuse structures 400 and 450 each having a reverse biased PN junction according to the second embodiment of the present invention. The fuse structures 400 and 450 both have an anode area 402, a cathode area 412 and a fuse link area 422. Built on top of the first embodiment of the present invention, the cathode area 412 is smaller than the anode area 402. Referring to FIG. 4A, the reverse biased PN junction is formed at a location 424, which is close to a middle section of the fuse link area 422 reflecting the fuse structure 300 shown in FIG. 3. Referring to FIG. 4B, the reverse biased PN junction is formed instead at a location 454 which is approximately an interface of the fuse link area 422 and the cathode area 412. In such a way, the fuse structure 450 also benefits from the cathode depletion effect, which makes the fuse programming even easier than in the case where the reverse biased PN junction is at the middle of the fuse link area.

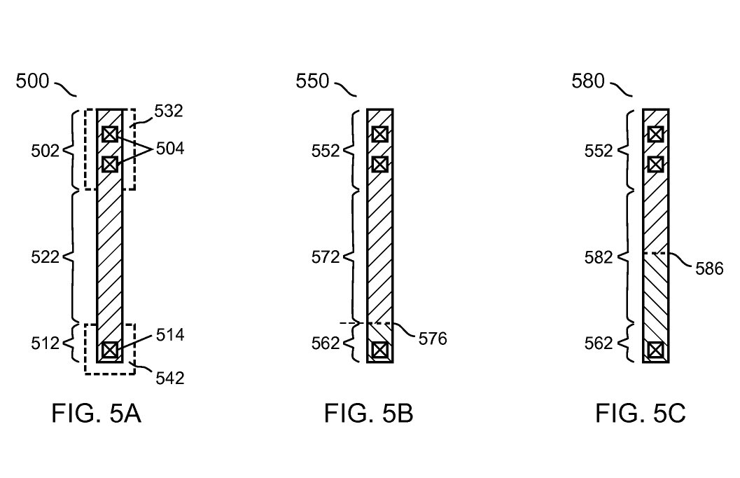

FIG. 5A illustrates a compact electrical fuse structure 500 according to a third embodiment of the present invention. More compact fuse structures are always preferred. But certain design rules, such as an anode area 502 or a cathode area 512 should overlay their respective contacts 504 and 514 by a certain amount to fully utilize current density of the contacts 504 and 514. Then the anode 502 and cathode 512 would be doted line enclosed areas 532 and 542, respectively, which are larger than the shaded anode area 502 and cathode area 512, respectively. According to the third embodiment of the present invention, the fuse structure 500 is a narrow strip that occupies less space than conventional, design rule abiding fuse structures. By reducing a terminal, i.e., the anode 502 or cathode 512, overlaying contacts 504 or 514, the current density at the contacts 504 or 514 may be restricted, which makes the contacts 504 or 514 also prone to the EM effect. This should be avoided in normal circuits, but is desirable in fuse applications, as the more severe the EM effect, the easier the fuse to be programmed and the larger the resistance differentiation between a before and after programming. In this case, the contact EM effect adds to the fuse link EM effect. A large resistance differentiation may be realized on this fuse structure 500.

FIG. 5B illustrates another compact electrical fuse structure 550 having a reverse biased PN junction according to a combination of the second and third embodiment of the present invention. Apparently, if the fuse structure 550 is made of silicided polysilicon, a PN junction may be formed in the polysilicon. Referring to FIG. 5B, an anode area 552 and a fuse link area 572 are implanted with N-type ions, and a cathode area 562 is implanted with P-type ions, then a reverse biased PN junction is formed at an interface location 576 which is near the cathode area 562. Therefore, the reverse biased PN junction serves to shun current to the silicide as well as to cause a cathode depletion effect, both of which intensify the EM effect in the fuse structure.

FIG. 5C illustrates yet another compact electrical fuse structure 580 having a reverse biased PN junction according to the combination of the second and third embodiment of the present invention. The fuse structure 580 differs from the fuse structure 550 only in that the reverse biased PN junction interface in the fuse structure 580 is created at a location 586 approximate to a middle section of the fuse link area 582. Similarly, the reverse biased PN junction shuns current to the silicide, which provides boosts to the EM effect on the electrical fuse structure 580.

Beside the aforementioned functionality advantages, the present invention may also be a cost down solution for anyone needing a fuse in an IC, as the poly fuse structure may be fabricated in a normal logic process without employing any additional mask.

Although the silicide on top of the polysilicon is described as embodiments of the present invention, one having skills in the arts would appreciate the bottom polysilicon layer may be replaced by other materials, such as diffusion, as long as a PN junction can be formed therein. Forming the top silicide layer may also be substituted by other processes as long as the top layer is subject to the EM effect. In another aspect, the layer subject to the EM effect may be at the bottom and the layer with reverse biased PN junction may be on the top.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

1. A fuse structure for being used in electromigration programming modes, the fuse structure comprising:
an anode area overlaying a first plurality of contacts that are coupled to a positively high voltage during a programming of the fuse structure;
a cathode area overlaying a second plurality of contacts that are coupled to a complementary low voltage during a programming of the fuse structure; and
a fuse link area having a first end and a second end,
wherein the first end contacts the anode area at a predetermined distance to the nearest of the first plurality of contacts, and the second end contacts the cathode area at the predetermined distance to the nearest of the second plurality of contacts,
wherein a width of the fuse link area at the first end and the second end is equal to a width of the anode area and the cathode area for aggravating the electromigration effect at the contacts.

2. The fuse structure of claim 1, wherein the anode, cathode and fuse link areas comprise the same first material.

3. The fuse structure of claim 2, wherein the first material is selected from the group consisting of polysilicon, diffusion active, silicide and silicided polysilicon.

4. The fuse structure of claim 1, wherein the width of the fuse link at the first end is equal to or smaller than the width of the anode area at approximately the same location.

5. The fuse structure of claim 1, wherein the width of the fuse link at the second end is larger than or equal to the width of the cathode area at approximately the same location.

6. The fuse structure of claim 1, wherein the cathode area overlays the second plurality of contacts by a distance smaller than specified by a predetermined design rule.

7. The fuse structure of claim 1, wherein the fuse link area comprises a reverse biased PN junction.

8. The fuse structure of claim 7, wherein the reverse biased PN junction is located at approximately a middle section of the fuse link.

9. A fuse structure for being used in electromigration (EM) programming modes, the fuse structure comprising:
an anode area overlaying a first plurality of contacts that are coupled to a positively high voltage during a programming of the fuse structure;
a cathode area overlaying a second plurality of contacts that are coupled to a complementary low voltage during a programming of the fuse structure; and
a fuse link area having a first end and a second end and having a stacked first and second layer,
wherein the first layer is subject to EM effect and the second layer contains a reverse biased PN junction during the programming,
wherein the first end contacts the anode area at a predetermined distance to the nearest of the first plurality of contacts, and the second end contacts the cathode area at the predetermined distance to the nearest of the second plurality of contacts,
wherein a width of the fuse link area at the first end and the second end is equal to a width of the anode area and the cathode area for aggravating the electromigration effect at the contacts.

10. The fuse structure of claim 9, wherein the width of the fuse link at the first end is equal to or smaller than the width of the anode area at approximately the same location.

11. The fuse structure of claim 9, wherein the width of the fuse link at the second end is larger than or equal to the width of the cathode area at approximately the same location.

12. The fuse structure of claim 9, wherein the cathode area overlays the second plurality of contacts by a distance smaller than specified by a predetermined design rule.

13. The fuse structure of claim 9, wherein the reverse biased PN junction is located at approximately a middle section of the fuse link.

14. A fuse structure for being used in electromigration programming modes, the fuse structure comprising:
an anode area overlaying a first plurality of contacts that are coupled to a positively high voltage during a programming of the fuse structure;
a cathode area overlaying a second plurality of contacts that are coupled to a complementary low voltage during a programming of the fuse structure, wherein the cathode area overlays the second plurality of contacts by a distance smaller than specified by a predetermined design rule; and
a fuse link area having a first end and a second end,
wherein the first end contacts the anode area at a predetermined distance to the nearest of the first plurality of contacts, and the second end contacts the cathode area at the predetermined distance to the nearest of the second plurality of contacts,
wherein a width of the fuse link area at the first end and the second end is equal to a width of the anode area and the cathode area for aggravating the electromigration effect at the contacts.

15. The fuse structure of claim 14, wherein the anode, cathode and fuse link areas comprise the same first material.

16. The fuse structure of claim 15, wherein the first material is selected from the group consisting of polysilicon, diffusion active, silicide and silicided polysilicon.

17. The fuse structure of claim 14, wherein the width of the fuse link at the first end is equal to or smaller than the width of the anode area at approximately the same location.

18. The fuse structure of claim 14, wherein the width of the fuse link at the second end is larger than or equal to the width of the cathode area at approximately the same location.

19. The fuse structure of claim 14, wherein the fuse link area comprises a reverse biased PN junction.

20. The fuse structure of claim 19, wherein the reverse biased PN junction is located at approximately the second end.
